(19) United States
(12) Patent Application Publication
(10) Pub. No.: US 2014/0063983 A1
(43) Pub. Date: Mar. 6, 2014

(54) Error Detection And Correction In A Memory System

(71) Applicant: David M. Daly, Croton-on-Hudson, NY (US)

(72) Inventor: David M. Daly, Croton-on-Hudson, NY (US)

(73) Assignee: International Business Machines Corporation, Armonk, NY (US)

(21) Appl. No.: 13/605,041

(22) Filed: Sep. 6, 2012

(51) Int. Cl. G11C 7/00

(52) U.S. Cl. 365/189.011

(57) ABSTRACT

A method including providing a plurality of random access memories having at least a first region, a second region and a third region; storing protected data on the first region on at least two of the random access memories, where the protected data is stored distributed among the at least two random access memories of the first region; storing parity information for the protected data on the second region on at least a third one of the random access memories; and storing unprotected data on the third region.

### TECHNICAL FIELD

The exemplary embodiments of this invention relate generally to computer memory and, more specifically, relate to error detection and correction in a memory system.

### BACKGROUND

This section endeavors to supply a context or background for the various exemplary embodiments of the invention as recited in the claims. The content herein may comprise subject matter that could be utilized, but not necessarily matter that has been previously utilized, described or considered. Unless indicated otherwise, the content described herein is not considered prior art, and should not be considered as admitted prior art by inclusion in this section.

The following abbreviations are utilized herein:

CRC cyclic redundancy check
DDR double data rate
DED double-bit error detection
DIMM dual in-line memory module
DRAM dynamic random access memory
ECC error correction code
EPROM erasable programmable read only memory
HDD hard disk drive
IPL initial program load
LRC longitudinal redundancy check
NVS nonvolatile storage
RAID redundant array of inexpensive/independent disks
RAM random access memory
SDR single data rate
SDRAM synchronous dynamic random access memory
SEC single-bit error correction
UE uncorrectable error
XOR exclusive OR

Computer systems often require a considerable amount of high speed RAM to hold information such as operating system software, programs and other data while a computer is powered on and operational. This information is normally binary, composed of patterns of 1's and 0's known as bits of data. The bits of data are often grouped and organized at a higher level. A byte, for example, is typically composed of 8 bits, although it may be composed of additional bits (e.g. 9, 10, etc.) when the byte also includes information for use in the identification and/or correction of errors. This binary information is normally loaded into RAM from NVS such as HDDs during power on and IPL of the computer system (e.g., boot up). The data is also paged-in from and paged-out to NVS during normal computer operation. In general, all the programs and information utilized by a computer system cannot fit in the smaller, more costly DRAM. In addition, even if it did fit the data would be lost when the computer system is powered off. At present, it is common for NVS systems to be built using a large number of HDDs.

Computer RAM is often designed with pluggable subsystems, often in the form of modules, so that incremental amounts of RAM can be added to a computer, as dictated by the specific memory requirements for the system and/or application. The acronym “DIMM” refers to dual in-line memory modules, a common type of memory modules that is currently in use. A DIMM is a thin, rectangular card comprising one or more memory devices, and may also include one or more registers, buffers, hub devices, and/or non-volatile storage (e.g., EEPROM) as well as various passive devices (e.g., resistors and/or capacitors), all mounted to the card. DIMMs are often designed with dynamic memory chips or DRAMs that are regularly refreshed to prevent the data stored within from being lost. Originally, DRAM chips were asynchronous devices, however contemporary chips, such as SDRAM (e.g., SDR, DDR, DDR2, DDR3, etc.), have synchronous interfaces to improve performance. DDR devices are available that use pre-fetching along with other speed enhancements to improve memory bandwidth and reduce latency. DDR3, for example, has a standard burst length of 8.

Memory device densities have continued to increase as computer systems have become more powerful. Currently it is not uncommon to have the RAM content of a single computer be composed of hundreds of trillions of bits. Unfortunately, the failure of just a portion of a single RAM device can cause the entire computer system to fail. When memory errors occur, which may be “hard” (repeating) or “soft” (one-time or intermittent) failures, these failures may occur as single cell, multi-bit, full chip or full DIMM failures and all or part of the system RAM may be unusable until it is repaired. Repair turn-around times can be hours or even days, which can have a substantial impact on a business dependent on the computer systems. The probability of encountering a RAM failure during normal operations has continued to increase as the amount of memory storage and complexity continues to grow in contemporary computers.

Techniques to detect and correct bit errors have evolved into an elaborate science over the past several decades. Perhaps the most basic detection technique is the generation of odd or even parity where the number of 1's or 0's in a data word are “exclusive or-ed” (XOR-ed) together to produce a parity bit. For example, a data word with an even number of 1's will have a parity bit of 0 and a data word with an odd number of 1's will have a parity bit of 1, with this parity bit data appended to the stored memory data. If there is a single error present in the data word during a read operation, it can be detected by regenerating parity from the data and then checking to see that it matches the stored (originally generated) parity.

Richard Hamming recognized that the parity technique could be extended to not only detect errors, but correct errors by appending an XOR field (e.g., an ECC field) to each code word. The ECC field is a combination of different bits in the word XOR-ed together so that errors (small changes to the data word) can be easily detected, pinpointed and corrected. The number of errors that can be detected and corrected are directly related to the length of the ECC field appended to the data word. The technique includes ensuring a minimum separation distance between valid data words and code word combinations. The greater the number of errors desired to be detected and corrected, the longer the code word, thus creating a greater distance between valid code words. The smallest distance between valid code words is known as the minimum Hamming distance.

These error detection and error correction techniques are commonly used to restore data to its original/correct form in noisy communication transmission media or for storage media where there is a finite probability of data errors due to the physical characteristics of the device. The memory devices generally store data as voltage levels representing a 1 or a 0 in RAM and are subject to both device failure and state changes due to high energy cosmic rays and alpha particles. Similarly, HDDs that store 1's and 0's as magnetic fields on a magnetic surface are also subject to imperfections in the magnetic media and other mechanisms that can cause undesired changes in the data pattern from what was originally stored.

In the 1980's, RAM memory device sizes first reached the point where they became sensitive to alpha particle hits and cosmic rays causing memory bits to flip. These particles do not damage the device but can create memory errors. These are known as soft errors, and most often affect just a single bit. Once identified, the bit failure can be corrected by simply rewriting the memory location. The frequency of soft errors has grown to the point that it has a noticeable impact on overall system reliability.

Memory ECCs, like those proposed by Hamming, use a combination of parity codes in various bit positions of the data word to allow detection and correction of errors. Every time data words are written into memory, a new ECC word needs to be generated and stored with the data, thereby allowing detection and correction of the data in cases where the data read out of memory includes an ECC code that does not match a newly calculated ECC code generated from the data being read.

The first ECCs were applied to RAM in computer systems in an effort to increase fault-tolerance beyond that allowed by previous means. Binary ECC codes were deployed that allowed for DED and SEC. This SEC/DED ECC also allowed for transparent recovery of single bit hard errors in RAM. Scrubbing routines were also developed to help reduce memory errors by locating soft errors through a complement/re-complement process so that the soft errors could be detected and corrected.

### BRIEF SUMMARY

In one exemplary embodiment a method is provided comprising providing a plurality of random access memories having at least a first region, a second region and a third region; storing protected data on the first region on at least two of the random access memories, where the protected data is stored distributed among the at least two random access memories of the first region; storing parity information for the protected data on the second region on at least a third one of the random access memories; and storing unprotected data on the third region.

In another aspect, an example method comprises providing a plurality of random access memories including a first region, a second region and a third region; storing protected data on the first region on at least two of the random access memories; storing parity information for the protected data on the second region on at least a third one of the random access memories; storing unprotected data on the third region; writing new protected data to the at least two random access memories; computing updated parity information based on the new protected data; and writing the updated parity information to the second region of the plurality of random access memories.

In another aspect, an example method comprises providing a plurality of random access memories comprising a first region, a second region and a third region; storing protected data on the first region on at least two of the random access memories; storing parity information for the protected data on the second region on at least a third one of the random access memories; storing unprotected data on the third region; in response to a command to write new protected data to one of the random access memories that has failed of the at least two random access memories, reading other protected data from other ones of the at least two random access memories and reading the parity information from the second region; reconstructing missing protected data for the failed random access memory based on the other protected data and the parity information; determining new parity information based on the new protected data and the reconstructed missing protected data; and writing the new parity information to the second region.

### BRIEF DESCRIPTION OF THE SEVERAL VIEWS OF THE DRAWINGS

The foregoing and other aspects of embodiments of this invention are made more evident in the following Detailed Description, when read in conjunction with the attached Drawing Figures, wherein:

FIG. 1 depicts an exemplary computer system comprised of an integrated processor chip connected to a plurality of cascaded interconnect memory modules;

FIG. 2 depicts an exemplary memory structure with cascaded memory modules and unidirectional busses;

FIG. 3 illustrates an exemplary system within which the exemplary embodiments of the invention may be utilized;

FIG. 4 illustrates an exemplary system with a memory module failure within which the exemplary embodiments of the invention may be utilized;

FIG. 5 illustrates a block diagram of an exemplary system in which various exemplary embodiments of the invention may be implemented;

FIGS. 6-9 illustrate various exemplary methods for performing read and write operations in accordance with the exemplary embodiments of the invention; and

FIG. 10 depicts a flowchart illustrating one non-limiting example of a method for practicing the exemplary embodiments of this invention.

### DETAILED DESCRIPTION

Some storage manufacturers have used advanced ECC techniques, such as Reed-Solomon codes, to correct for full memory chip failures. Some memory system designs also have standard reserve memory chips (e.g., “spare” chips) that can be automatically introduced in a memory system to replace a faulty chip. These advancements have greatly improved RAM reliability, but as memory size continues to grow and customers' reliability expectations increase, further enhancements are needed. There is the need for systems to survive a complete DIMM failure and for the DIMM to be replaced concurrent with system operation. In addition, other failure modes must be considered which affect single points of failure between one or more DIMMs and the memory controller/embedded processor. For example, some of the connections between the memory controller and the memory device(s) may include one or more intermediate buffer(s) that may be external to the memory controller and reside on or separate from the DIMM, however upon its failure, may have the effect of appearing as a portion of a single DIMM failure, a full DIMM failure, or a broader memory system failure, for example.

Although there is a clear need to improve computer RAM reliability (also referred to as “fault tolerance”) by using even more advanced error correction techniques, attempts to do this have been hampered by various factors, including impacts to available customer memory, performance, space, and heat. Using redundancy by including extra copies (e.g., “mirroring”) of data or more sophisticated error coding techniques drives up costs, adds complexity to the design, incurs additional overhead, and may impact another key business measure: time-to-market. For example, the simple approach of memory mirroring has been offered as a feature by several storage manufacturing companies. The use of memory mirroring permits systems to survive more catastrophic memory failures, but acceptance has been very low because it generally requires a doubling of the memory size on top of the base SEC/DEC ECC already present in the design, which generally leaves customers with less than 50% of the installed RAM available for system use. ECC techniques have been used to improve availability of storage systems by correcting HDD failures so that customers do not experience data loss or data integrity issues due to failure of a HDD, while further protecting them from more subtle failure modes.

Some suppliers of storage systems have successfully used RAID techniques to improve availability of HDDs to computer RAM. In many respects it is easier to recover from a HDD failure using RAID techniques because it is much easier to isolate the failure in HDDs than it is in RAM. HDDs often have embedded checkers such as ECCs to detect bad sectors. In addition, CRCs and LRCs may be embedded in HDD electronics and/or disk adapters, or there may be checkers used by higher levels of code and applications to detect HDD errors. CRCs and LRCs are written coincident with data to help detect data errors. CRCs and LRCs are hashing functions used to produce a small substantially unique bit pattern generated from the data. When the data is read from the HDD, the check sum is regenerated and compared to that stored on the platter. The signatures must match exactly to ensure the data retrieved from the magnetic pattern encoded on the disk is as was originally written to the disk.

RAID systems have been developed to improve performance and/or to increase the availability of disk storage systems. RAID distributes data across several independent HDDs. There are many different RAID schemes that have been developed with each having different characteristics and different pros and cons associated with them. Performance, availability, and utilization/efficiency (the percentage of the disks that actually hold customer data) are among the most important aspects. The tradeoffs associated with various RAID schemes have to be carefully considered because improvements in one attribute can often result in reductions in another. For example, a RAID-1 system uses two exact copies (mirrors) of the data. Clearly, this has a negative impact on utilization/efficiency while providing additional reliability (e.g., a failure of one copy of the data is not fatal since the remaining copy can be used). As another example, a RAID-0 system (stripe set or striped volume) splits data evenly across two or more disks. This can improve performance (since each disk can be read concurrently, resulting in faster reads) while reducing reliability (since failure of only one disk will lead to system failure).

There is some inconsistency and ambiguity in RAID-related terminology used throughout the industry. The following definitions are what is implied by use of these terms in this disclosure unless otherwise stated. An array is a collection of hard disk drives in which one or more instances of a RAID erasure code is implemented. A symbol or an element is a fundamental unit of data or parity, the building block of the erasure codes. In coding theory, this is the data assigned to a bit within the symbol. This is typically a set of sequential sectors. An element is composed of a fixed number of bytes. It is also common to define elements as a fixed number of blocks. A block is a fixed number of bytes. A stripe is a complete and connected set of data and parity elements that are dependently related to the parity computation relations. In coding theory, the stripe is the code word or code instance. A strip is a collection of contiguous elements on a single hard disk drive. A strip contains data elements, parity elements or both from the same disk and stripe. The term strip and column are used interchangeably. In coding theory, the strip is associated with the code word and is sometime called the stripe unit. The set of strips in a code word form a stripe. It is most common for strips to contain the same number of elements. In some cases stripes may be grouped together to form a higher level construct know as a stride.

As noted above, RAID-0 is striping of data across multiple HDDs to improve performance. RAID-1 is mirroring of data, keeping two exact copies of the data on two different HDDs to improve availability and prevent data loss. Some RAID schemes can be used together to gain combined benefits. For example, RAID-10 is both data striping and mirroring across several HDDs in an array to improve both performance and availability.

RAID-3, RAID-4 and RAID-5 are very similar in that they use a single XOR check sum to correct for a single data element error. RAID-3 is byte-level striping with dedicated parity HDD. RAID-4 uses block level striping with a dedicated parity HDD. RAID-5 is block level striping like RAID-4, but with distributed parity. There is no longer a dedicated parity HDD. Parity is distributed substantially uniformly across all the HDDs, thus eliminating the dedicated parity HDD as a performance bottleneck. The key attribute of RAID-3, RAID-4 and RAID-5 is that they can correct a single data element fault when the location of the fault can be pinpointed (e.g., through some independent means).

There is no single universally accepted industry-wide definition for RAID-6. In general, RAID-6 refers to block or byte-level striping with dual checksums. An important attribute of RAID-6 is that it allows for correction of up to two data element faults when the faults can be pinpointed through some independent means. It also has the ability to pinpoint and correct a single failure when the location of the failure is not known.

Another very important computer system attribute that can easily be overlooked is that not all memory failures are equal. For example, DIMM, channel and buffer chip failures are single points of failure and, thus, are not protectable by usage of an ECC. As another example, if hypervisor data on an affected DIMM were to fail, it would cause a system failure disrupting overall system operation.

One technique for protecting such high importance elements and/or partitions is to utilize selective memory mirroring. This technique selectively protects sensitive information or data at a comparatively high costs (e.g., 100% overhead in memory capacity due to the mirroring). Since the overhead is high, this technique may not be suitable for usage with all partitions. However, this technique may be suitable for important and/or critical elements (e.g., hypervisor-related elements).

There is a need in the art to improve failure detection and correction in memory systems. For example, it would be desirable for a memory system to be able to survive a complete DIMM failure and/or for the DIMM to be replaced concurrent with system operation.

The exemplary embodiments of the invention utilize a RAID-like structure in conjunction with parity data to provide comprehensive fault protection for a memory system. As an example, utilization of the exemplary embodiments of the invention, as discussed in further detail below, will enable continued operation even in the face of difficult faults, such as a DIMM failure, for example. Previously, such a failure, were it to occur for a DIMM holding sensitive or important information, could lead to system failure. Furthermore, the overhead required for providing such fault protection is much less than 100%, as will be illustrated herein.

In one exemplary embodiment of the invention, a number of memory modules (e.g., DIMMs) are coupled to a number of memory controllers via a number of channels. The channels, and corresponding memory modules, are separated into data channels and one parity channel. The parity channel/module stores parity information based on the data channels/modules. As an example, the parity information may be obtained by XOR-ing the data channels. As an example, for a four channel system there may be three data channels and one parity channel. By storing parity information, a failure of any one module (e.g., DIMM) is recoverable, for example, by recomputing the lost data/information using the parity information. In addition, once the lost data/information is recomputed, normal operations can proceed which may involve using the recomputed data/information to update the parity information and store the updated parity information. This arrangement is particularly useful given that in conventional systems and arrangements some critical faults (e.g., loss of an entire DIMM) would cripple the system and disallow further operations. In addition, no additional or special hardware is needed and the overhead incurred is less than the 100% for full mirroring of the data (e.g., 33% for the four-channel system noted above). The below descriptions, particularly with reference to the figures, provide further information concerning the various exemplary embodiments of the invention.

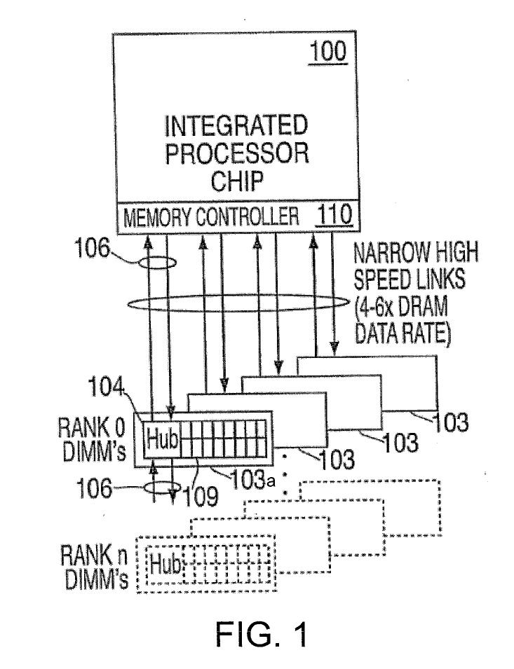

FIG. 1 depicts an exemplary computer system comprised of an integrated processor chip 100, which contains one or more processor elements and an integrated memory controller 110. In the configuration depicted in FIG. 1, multiple independent cascade interconnected memory interface busses 106 are logically aggregated together to operate in unison to support a single independent access request at a higher bandwidth with data and error detection/correction information distributed or “striped” across the parallel busses and associated devices. The memory controller 110 attaches to four narrow/high speed (e.g., at 4-6×DRAM data rate) point-to-point memory busses 106, with each bus 106 connecting one of the several unique memory controller interface channels to a cascade interconnect memory subsystem 103 (or memory module, e.g., a DIMM) which includes at least a hub device 104 and one or more memory devices 109 (individual memories). Some systems further enable operations when a subset of the memory busses 106 are populated with memory modules 103. In this case, the one or more populated memory busses 108 may operate in unison to support a single access request. There may be a plurality of ranks comprised of groups of the modules 103 (e.g., groups of DIMMs), extending from rank 0 (module 103a) to rank n.

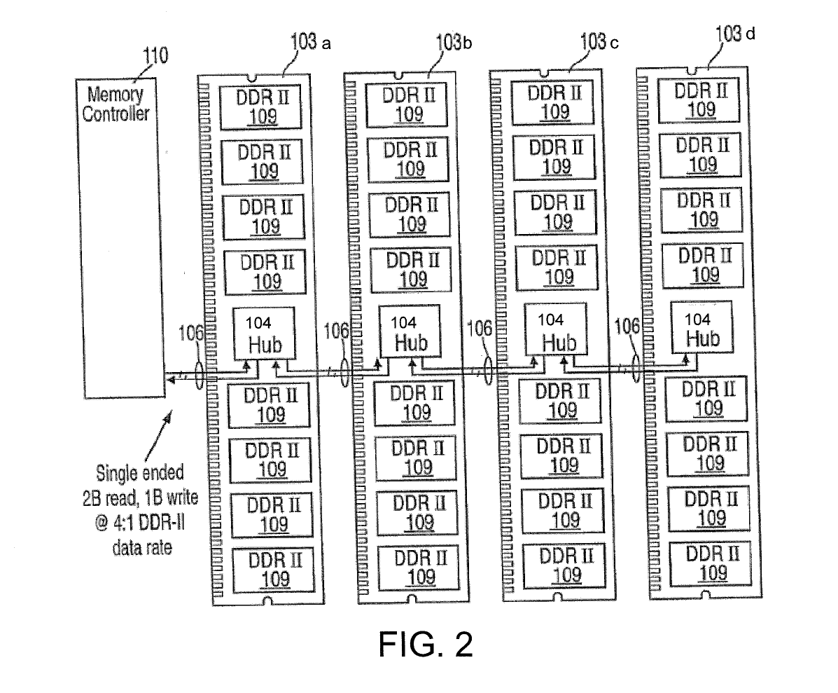

FIG. 2 depicts an exemplary memory structure with cascaded memory modules 103 and unidirectional busses 106. One of the functions provided by the hub devices 104 in the memory modules 103 in the cascade structure is a re-drive function to send signals on the unidirectional busses 106 to other memory modules 103 or to the memory controller 110. FIG. 2 includes the memory controller 110 and four memory modules 103a, 103b, 103c, 103 d, on each of two memory busses 106 (e.g., a downstream memory bus with 24 wires and an upstream memory bus with 25 wires), connected to the memory controller 110 in either a direct or cascaded manner. The memory module 103a next to the memory controller 110 is connected to the memory controller 110 in a direct manner. The other memory modules 103b, 103c, 103d are connected to the memory controller 110 in a cascaded manner. Although not shown in this figure, the memory controller 110 may be integrated in the processor 100 and may connect to more than one memory bus 106 as depicted in FIG. 1.

As shown in FIG. 2, since this is a cascaded arrangement the hub device 104 on each module 103 is connected to one or more other such hub devices 104 on one or more other such modules 103. The hub device 104 on each module 103 is connected to the memory devices 109 on that module 103 and, generally, enables and/or oversees operations on information stored on the memory devices 109 (e.g., enables and/or oversees read, write, checksum and/or error checking/correction operations). As a non-limiting example, the hub device 104 may comprise a buffer chip and/or a memory controller.

While shown in FIG. 2 with the memory controller 110 being connected to a single rank 0 DIMM 103a, it should be appreciated that the memory controller 110 may be connected to a plurality of rank 0 DIMMs 103, as shown in FIG. 1. The illustration in FIG. 2 is merely an exemplary arrangement used to show further details of the system in FIG. 1. It should further be appreciated that one or both of the exemplary systems depicted in FIGS. 1 and 2 may be utilized in conjunction with the exemplary embodiments of the invention as described herein.

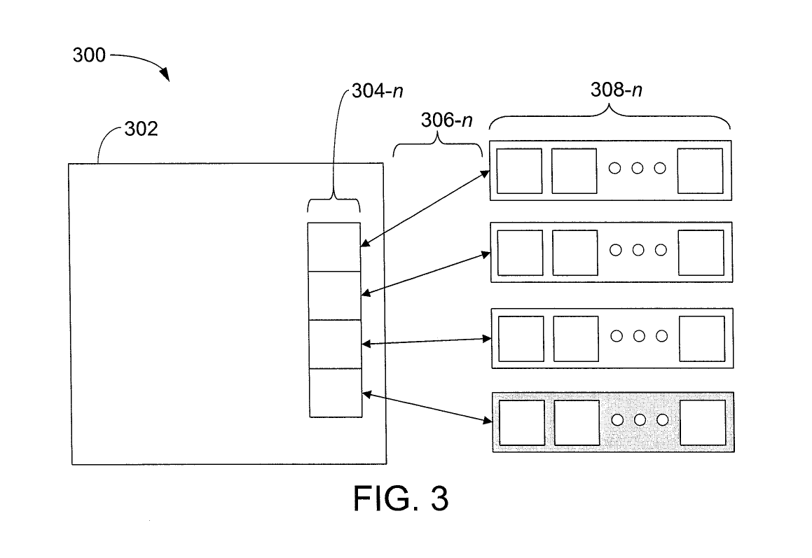

FIG. 3 illustrates an exemplary system 300 within which the exemplary embodiments of the invention may be utilized. The exemplary system 300 includes a microprocessor 302 having at least one memory controller 304-n that is coupled via a plurality of channels 306 to a plurality of memory modules 308 (e.g., DIMMs). The individual channels 306 and corresponding memory modules 308 will be referred to individually as 306-n and 308-n, accordingly. In the exemplary system 300 of FIG. 3, it should be noted that since there are four channels 306 and four memory modules 308, n will take a value from 1 to 4, thus identifying the first through fourth memory controller 304, channel 306 and/or memory module 308. It is further noted that for ease of discussion, the memory modules 308 may be referred to as DIMMs. This is merely exemplary and should not be construed as limiting the exemplary embodiments in any manner since the memory modules 308 may take any suitable form according to the desired technological application.

While shown in FIG. 3 with four memory controllers 304, in other exemplary embodiments a different number of memory controllers may be used, including more than four or less than four, depending on the implementation. Generally, and as shown in FIG. 3, each such memory controller 304-n oversees one corresponding channel 306-n for communicating with one or more corresponding memory modules 308-n (e.g., more than one if cascaded). In further exemplary embodiments, an individual memory controller 304-n may oversee more than one channel 306 and/or more than one memory module 308. In other exemplary embodiments, a memory controller 304 can communicate with more than one memory module 308 (e.g., more than one DIMM) via a single channel 306. Furthermore, while shown in FIG. 3 with four memory modules 308 (e.g., four DIMMs), in other exemplary embodiments a different number of memory modules may be used, such as eight memory modules, as a non-limiting example. While not shown in FIG. 3, it should be appreciated that each memory module 308 may include one or more registers, buffers, buffer chips, hub devices and/or non-volatile storage (e.g., EPROM).

In the exemplary system 300 of FIG. 3, a line is cached from one channel. Each line may include 64, 128 or 256 bytes of data, as non-limiting examples. In accordance with the exemplary embodiments of the invention, of the four DIMMs 308, the first three 308-1, 308-2, 308-3 store data whereas the fourth DIMM 308-4 stores parity information based on the data stored on the other three DIMMs 308-1, 308-2, 308-3. Note that in this exemplary embodiment, there is a 33% capacity overhead for the protected region. That is, the coverage includes 3 cache lines combined with 1 parity line across 4 channels.

It should be appreciated that while the exemplary embodiments of the invention are discussed herein with respect to protected information/data, the configuration is fully selectable such that any fraction of the total memory is protectable. For example, the parity information on the fourth DIMM 308-4 may only cover a portion (i.e., less than all) of the data stored on the DIMMs 308-1, 308-2, 308-3. In such a case, and by extension, it may be that not all of the fourth DIMM 308-4 is used for parity information and a portion of the fourth DIMM 308-4 may be used for data storage. In such a manner, and in accordance with some exemplary embodiments of the invention, the above-noted exemplary 33% overhead may constitute a maximum overhead with some cases having less than 33% overhead (e.g., if less than all of the information is protected with the parity information). As a non-limiting example, it may be the case that only important and/or critical information (e.g., hypervisor-related data) is protected with the parity information on the fourth DIMM 308-4.

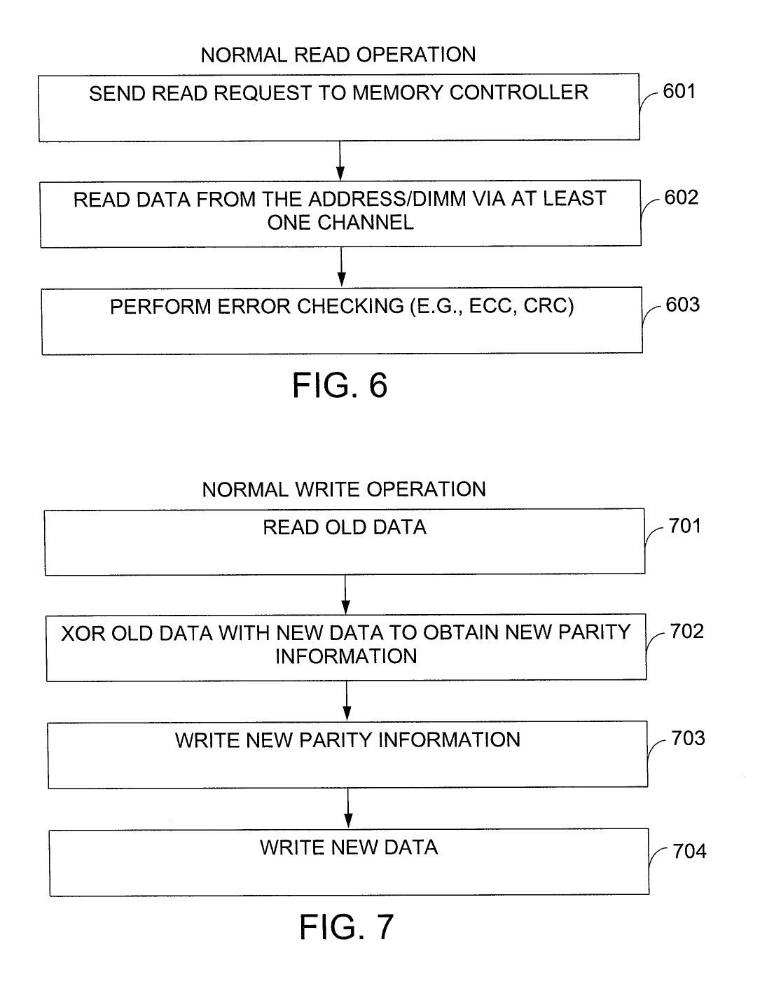

FIGS. 6-9 illustrate various exemplary methods for performing read and write operations in accordance with the exemplary embodiments of the invention, as described in further detail below.

During a normal read operation (FIG. 6), a request is sent to the memory controller 304 in question (601). The memory controller 304 reads the data from the DIMM/address via at least one channel (602). Upon receiving the data, the memory controller 304 performs ECC and CRC to check protection before responding to the initial request with the requested data (603). Note that this procedure is similar to a read operation for conventional memory and incurs no additional overhead (e.g., as compared to a system that does not store or use parity information). In some exemplary embodiments, it may be the case that a controller/device/component on the DIMM itself (e.g., a Hub device 104) is capable of performing some or all of the protection checking (e.g., ECC and/or CRC operations).

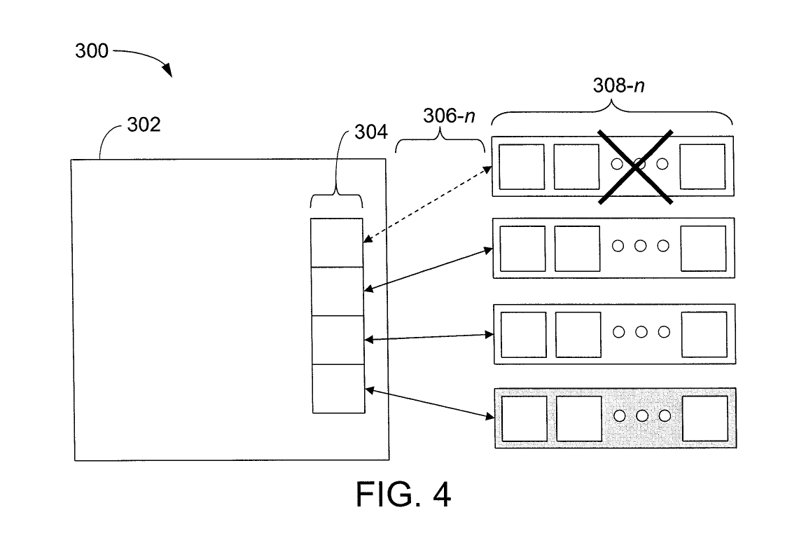

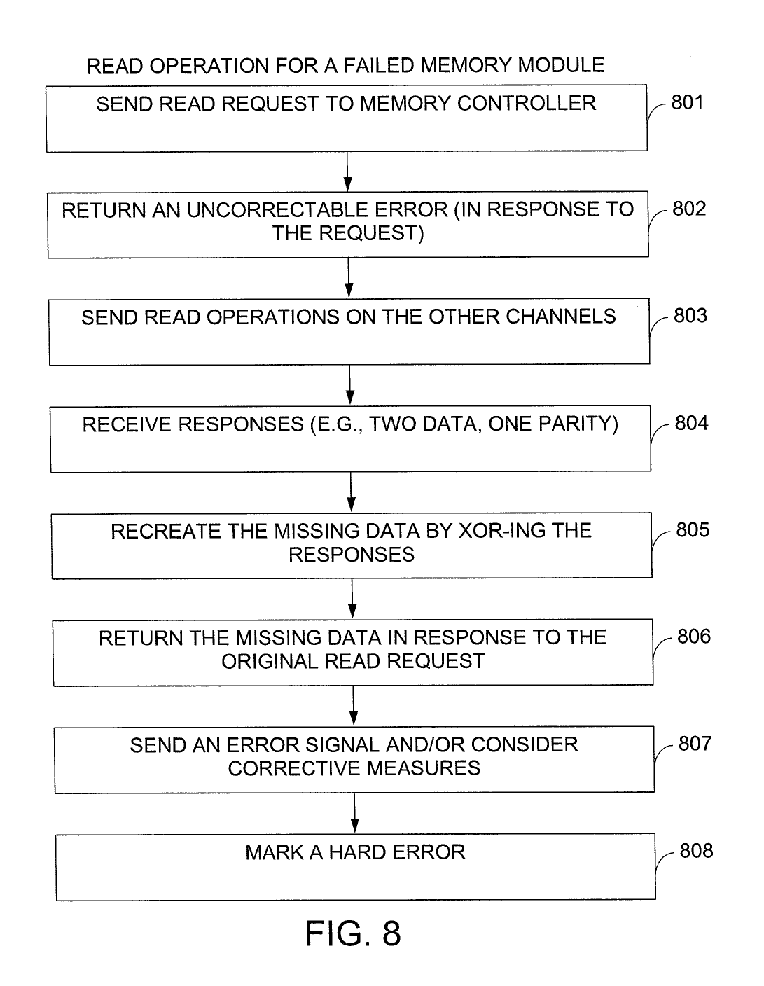

Next consider a read operation with a DIMM failure (FIGS. 4 and 8). For example, and as shown in FIG. 4, consider operations that were to occur if a read operation were sent to the first DIMM 308-1 and the first DIMM 308-1 failed. Initially, assume that the system 300 is unaware of the DIMM failure. Thus, the read operation (801) would be sent on the first channel 306-1 and would return as an UE (802). In response, and in accordance with the exemplary embodiments of the invention, the memory controller 304 would issue read operations (803) on the other three channels 306-2, 306-3, 306-4. Using the responses from these read operations (804), the memory controller 304 will XOR the results (805) in order to recreate the missing data from the bad channel and return the recreated data (806) in response to the original read request.

In further exemplary embodiments, the memory controller 304 can send an error signal and consider corrective/reconfiguration options (807), such as: scrub and retry data, deallocate the faulty sector(s) or “call home” (i.e., signal higher level errors) for example. The memory controller 304 may also mark a hard error (808). This will enable the memory controller 304 to skip the first two steps (i.e., the read sent to the faulty DIMM and the return of an UE) until the DIMM, which had the DIMM failure, is repaired or replaced. This is represented in FIG. 4 by the use of a dashed line for the first channel 306-1.

Note that the exemplary embodiments of the invention enable recreation of the data stored on the faulty DIMM 308-1 instead of trying to reread it. Furthermore, note that in the event of a DIMM failure (FIG. 4), three times the normal bandwidth (i.e., the bandwidth for a read operation on a non-failing DIMM) is additionally required (i.e., beyond the read operation on the failed DIMM), though accessing the functioning DIMMs may be performed in parallel; to minimize the additional time incurred (delay).

Next consider a normal write operation (FIG. 7) on the exemplary fully-functioning system 300 of FIG. 3. First, a read is issued for the “old” data (701). The new data is XOR-ed with the old data (702) and the results are sent on the parity channel to be written on the parity information/DIMM 308-4 (703). The new data is then written to the selected channel and replaces the old data (704). Note that the computations (e.g., the XOR operation) can be performed by the memory controller 304 or by a component on the DIMM (e.g., a buffer chip, hub device or other such component may perform RMW, read-modify-write). If the computations are performed by a component on the DIMM, this can save 1 read operation over having the memory controller 304 perform the operations (since the old data would not have to be sent to the memory controller 304). The overhead for these operations comes to 1 channel read, 2 DRAM reads (1 for the parity information and 1 for the old data) and 2 writes (1 for the parity information and 1 for the new data). This is in comparison to a conventional arrangement (i.e., one without parity) that would incur 1 channel read, 1 DRAM read and 1 write.

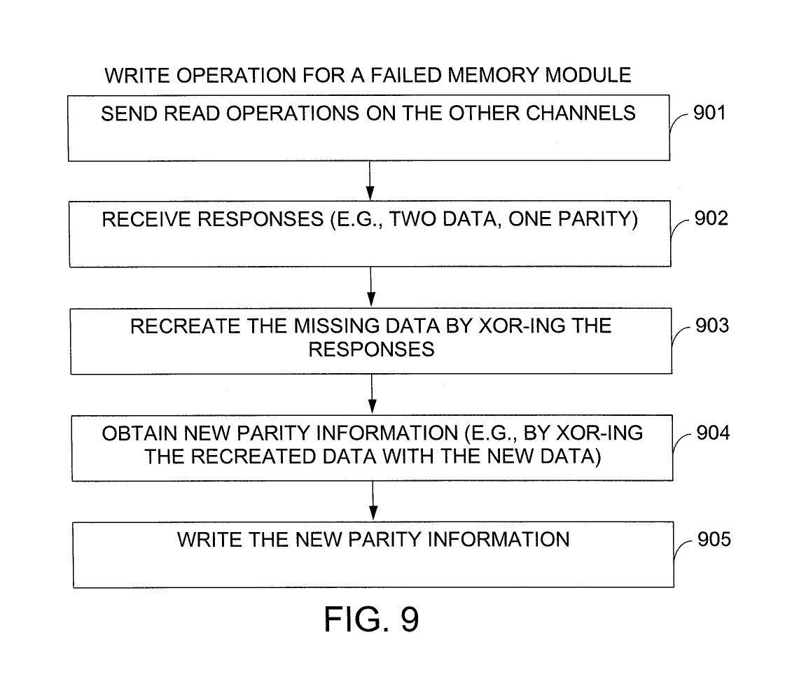

As illustrated in FIG. 9, a write operation with a DIMM failure (e.g., a write operation for the failed DIMM 308-1 in FIG. 4) proceeds in a similar manner as the read operation with a DIMM failure. That is, assume that the DIMM 308-1 is already marked as failed (e.g., as determined in steps 801 and 802 of FIG. 8). Thus, the system/memory controller 304 is aware that there is no need to write to the failed DIMM 308-1. However, the parity information on the fourth DIMM 308-4 can still be updated and preserved to reflect the new data. In order to do so, read commands are issued to the three, good DIMMS 308-2, 308-3, 308-4 via the two data channels 306-2, 306-3 and the parity channel 306-4, respectively (901). Responses are received from the three channels (902). From the read information (902), the original data (e.g., that would otherwise be available but for the failed DIMM 308-1) is recomputed by XOR-ing the data from the two data DIMMs 308-2, 308-3 and the parity information (903). New parity information is obtained, for example, by XOR-ing the recreated data with the new data (904). The new parity information is written back to the parity DIMM 308-4 via the parity channel 306-4 (905).

Thus, in accordance with the exemplary embodiments of the invention the overhead for a write operation on a failed DIMM 308-1 is three line reads and one line write. There is no need to write to the failed DIMM 308-1 unless trying to scrub and recreate, for example. While this may seem like a lot of overhead, recall that normally (e.g., in the absence of the parity information) this write operation is not possible. With conventional systems, the failed DIMM is usually declared “dead” and there cannot be any write operation for the data contained on the failed DIMM.

Note that if the DIMM is not already marked as failed, a few additional operations will occur, namely an attempt to write the data to the failed DIMM and a returning of an UE (e.g., similar to the initial steps 801, 802 previously noted for reading from a failed DIMM that has not already been marked). Additional operations may be performed subsequent to the write operations of FIG. 9, such as those of steps 807, 808 in FIG. 8, for example.

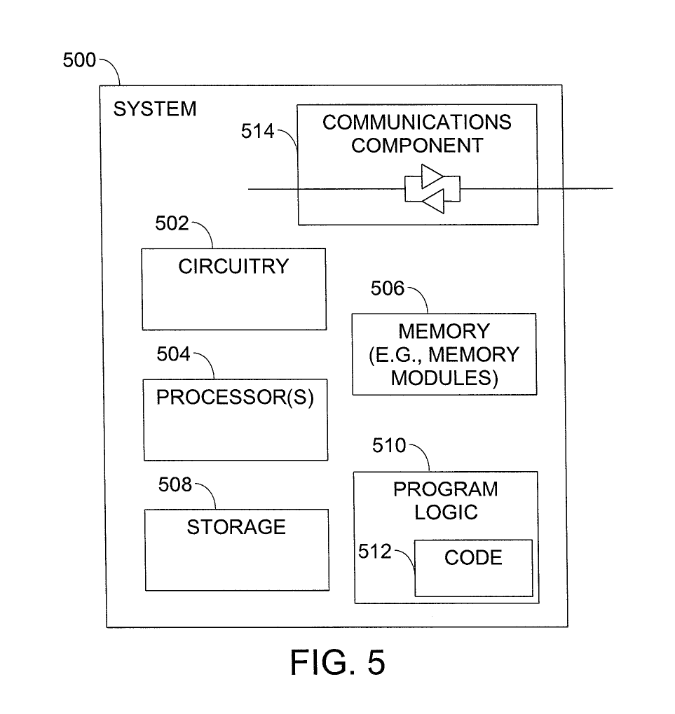

FIG. 5 illustrates a block diagram of an exemplary system 500 in which various exemplary embodiments of the invention may be implemented. The system 500 may include at least one memory 506 (e.g., a volatile memory device, a non-volatile memory device) and/or at least one storage 508. The system 500 may also include at least one circuitry 502 (e.g., circuitry element, circuitry components, integrated circuit) that may in certain exemplary embodiments include at least one processor 504 and/or form a component of the at least one memory 506 (e.g., one or more registers, buffers, hub devices, computer-readable storage mediums and/or non-volatile storage). The storage 508 may include one or more of a non-volatile memory device (e.g., EEPROM, ROM, PROM, RAM, DRAM, SRAM, flash, firmware, programmable logic, etc.), magnetic disk drive, optical disk drive and/or tape drive, as non-limiting examples. The storage 508 may comprise an internal storage device, an attached storage device and/or a network accessible storage device, as non-limiting examples. The system 500 may include at least one program logic 510 including code 512 (e.g., program code, a computer program, program instructions) that may be loaded into the memory 506 and executed by the processor 504 and/or circuitry 502. In certain exemplary embodiments, the program logic 510, including code 512, may be stored in the storage 508. In certain other exemplary embodiments, the program logic 510 may be implemented in the circuitry 502. Therefore, while FIG. 5 shows the program logic 510 separately from the other elements, the program logic 510 may be implemented and/or stored in the memory 506 and/or the circuitry 502, as non-limiting examples.

The system 500 may include at least one communications component 514 that enables communication with at least one other component, system, device and/or apparatus. As non-limiting examples, the communications component 514 may include a transceiver configured to send and receive information, a transmitter configured to send information and/or a receiver configured to receive information. As a non-limiting example, the communications component 514 may comprise a modem and/or network card. The system 500 of FIG. 5 may be embodied in a computer and/or computer system, such as a desktop computer, a portable computer or a server, as non-limiting examples. The components of the system 500 shown in FIG. 5 may be connected or coupled together using one or more internal buses, connections, wires and/or (printed) circuit boards, as non-limiting examples.

It should be noted that in accordance with the exemplary embodiments of the invention, one or more of the circuitry 502, processor(s) 504, memory 506, storage 508, program logic 510 and/or communications component 514 may store one or more of the various items (e.g., data, databases, tables, items, vectors, matrices, variables, equations, formula, operations, operational logic, logic) discussed herein. As a non-limiting example, one or more of the above-identified components may receive and/or store the data, information, parity information and/or instructions/operations/commands. As a further non-limiting example, one or more of the above-identified components may receive and/or store the function(s), operations, functional components and/or operational components, as described herein.

Further in accordance with the exemplary embodiments of the invention, the storage 508 may comprise one or more memory modules (e.g., memory cards, DIMMs) that are connected together in order to collectively function as described herein. For example, the storage 508 may comprise a plurality of cascaded interconnect memory modules (e.g., with unidirectional busses). In further exemplary embodiments, the processor(s) 504 and/or circuitry 502 may comprise one or more memory controllers. In some exemplary embodiments, a plurality of memory controllers is provided such that each memory controller oversees operations for at least one channel coupling the respective memory controller to a corresponding memory module (e.g., part or all of memory 506, a DIMM).

The exemplary embodiments of this invention may be carried out by computer software implemented by the processor 504 or by hardware, or by a combination of hardware and software. As a non-limiting example, the exemplary embodiments of this invention may be implemented by one or more integrated circuits. The memory 506 may be of any type appropriate to the technical environment and may be implemented using any appropriate data storage technology, such as optical memory devices, magnetic memory devices, semiconductor-based memory devices, fixed memory and removable memory, as non-limiting examples. The processor 504 may be of any type appropriate to the technical environment, and may encompass one or more of microprocessors, general purpose computers, special purpose computers and processors based on a multi-core architecture, as non-limiting examples.

In some exemplary embodiments, at IPL two address spaces may be initialized—one for the parity-protected data and one for the unprotected data. As a non-limiting example, for a total address space of size R, the parity-protected region may be of size 0.75 R. For example, the exemplary system discussed above in FIGS. 3 and 4 has four (4) channels; that is, there are 4 DIMMs. “N” represents the number of channels “4”. This may provide a total of 3 channels available for storage of parity-protected data (0.75 N=3), and 1 channel used for storage of the parity information. Assume there is Rc memory on each channel (e.g., 32 GB on each channel). Then, there is R memory behind the N channels (R=N*Rc). There are two address spaces; protected and not-protected. In the base scheme there is an address space of Rnp=R for the not protected space, and Rp=0.75 R for the protected space. The 0.75 is for N=4, and is (N−1)/N since one of the channels is being used logically for parity. There is then a mapping from the Rp and Rnp to the actual memory. The hypervisor may ensure that if a given address in Rp is allocated, that the corresponding addresses in Rnp are not used.

In other exemplary embodiments, different values of N may be available, such as N=8, for example. In further exemplary embodiments, the parity space may be of size ⅛ N (e.g., 7 data channels and 1 parity channel for 7 data memory modules and 1 parity memory module). In some exemplary embodiments, the address spaces may overlap. In such a case, and by way of example, the hypervisor may be responsible for allocating the spaces so as to prevent any overlap in the used memory (i.e., versus allocated/initialized).

In accordance with the exemplary embodiments of the invention, there is no additional overhead incurred on a normal read operation. Furthermore, conventional ECC, CRC and UE operations may be performed. For example, corrective measures may be implemented on a UE.

As noted above, for N=4 (e.g., four channels, four DIMMs, one channel/DIMM used for parity) write operations incur two line reads (parity line and original line) and two line writes (data line and updated parity line). Also as noted above, the overhead for writes to failed DIMMs include three line reads (the two good data lines and the old parity line) and one line write (updated parity line). There is no need to write to the failed DIMM unless attempting to scrub and recreate, for example. While a DIMM failure will necessitate usage of three times the normal bandwidth (due to the three reads), the DIMMs in the array may be accessed in parallel to minimize any further delays.

Also note that since the scope of protection is fully configurable, the additional overhead need not be incurred for all data. For example, there is no additional overhead for any non-protected data/regions.

The exemplary embodiments of the invention afford a number of advantages and benefits, discussed herein by way of non-limiting examples. The exemplary embodiments are capable of covering all memory errors. That is, the exemplary embodiments provide continued operation of the system even in the face of what would otherwise be crippling errors (e.g., if the failed DIMM 308-1 stored hypervisor data). Furthermore, the coverage is comprehensive in that it protects against errors in the memory controller 304, the channels 306 and the memory modules 308 (e.g., DIMMs), as non-limiting examples. The scope of protection is fully configurable such that it may be used to protect as much or as little of the data as desired (e.g., enabling selective control of overhead). In such a manner, the incurred overhead is similarly configurable/selectable. In addition, no packaging changes, such as any extra memory channels, are needed for implementation. In at least some cases, the exemplary embodiments of the invention can be implemented using existing hardware (e.g., operating with different software and/or logic). Furthermore, there is no read overhead on a normal read operation.

It is observed that while conventional systems may utilize parity information in conjunction with permanent or long-term storage (e.g., NVS, certain RAID arrays), the exemplary embodiments of the invention utilize parity information in conjunction with volatile memory (e.g., RAM, DRAM) to enable continued system operation even in the face of critical memory errors (e.g., UEs). In modern computing, there is a focus on uptime and reliability for critical systems. The exemplary embodiments of the invention enable more robust systems that are capable of continued performance despite errors that would otherwise cripple conventional systems.

Below are further descriptions of various non-limiting, exemplary embodiments of the invention. The below-described exemplary embodiments are numbered separately for clarity purposes. This numbering should not be construed as entirely separating the various exemplary embodiments since aspects of one or more exemplary embodiments may be practiced in conjunction with one or more other aspects or exemplary embodiments.

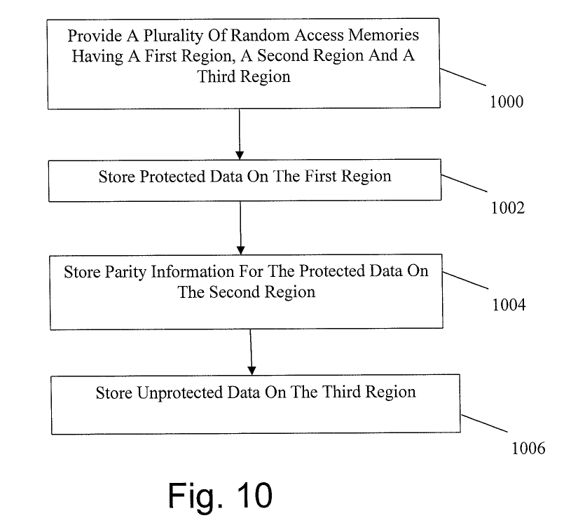

In one exemplary embodiment, and as illustrated in FIG. 10, a method comprising: providing a plurality of random access memories as indicated by block 1000 having a first region, a second region and a third region; storing protected data on the first region. as indicated by block 1002. on at least three of the random access memories, where the protected data is stored distributed among the at least three random access memories of the first region; storing parity information for the protected data on the second region on at least a forth one of the random access memories as indicated by block 1004; and storing unprotected data on the third region as indicated by block 1006. For example, for block 1002 protected data may be stored on the first three memory modules 308-1, 308-2 and 308-3. For block 1004, parity information for that protected data may be stored on the fourth memory module 308-4. For block 1006, the unprotected data may be stored on any of memory modules 308-1, 308-2, 308-3 and/or 308-4. Similarly, part of the protected data may be stored on the fourth memory module 308-4.

The method may further comprise dynamically varying a first amount of protected data and a second amount of unprotected data. A first size of the first region and a third size of the third region may be dynamically variable. The method may further comprise allocating a total memory space of the plurality of random access memories among a group consisting of the first region, the second region and the third region. The method may further comprise reallocating a total memory space of the plurality of random access memories among a group consisting of the first region, the second region, the third region and a fourth region of the plurality of random access memories, where the fourth region consists of a portion of the plurality of random access memories that has been determined to be inaccessible or unusable. The method may further comprise reallocating a total memory space of the plurality of random access memories among a group consisting of the first region, the second region, the third region and a fourth region of the plurality of random access memories, where the fourth region consists of a portion of the plurality of random access memories that is inaccessible or unusable. The first region, the second region and the third region might not overlap one another. The method may further comprise using the parity information to reconstruct a lost or inaccessible portion of the protected data. The method may further comprise, in response to an uncorrectable error occurring for one of the plurality of random access memories, continuing usage of remaining ones of the plurality of random access memories by using the parity information to reconstruct lost or inaccessible protected data. The parity information may enable reconstruction of a portion of protected data stored on a random access memory that fails. The method may further comprise writing new protected data to one of the plurality of random access memories; computing updated parity information based on the new protected data; and writing the updated parity information to the second region of the plurality of random access memories. The method may further comprise, in response to a command to write new protected data to a random access memory that has failed, reading other protected data from others of the plurality of random access memories and reading the parity information from the second region of the plurality of random access memories; reconstructing missing protected data for the failed random access memory based on the other protected data and the parity information; determining new parity information based on the new protected data and the reconstructed missing protected data; and writing the new parity information to the second region of the plurality of random access memories. The plurality of random access memories may consist of four memory modules. The plurality of random access memories may consist of eight memory modules.

In one example a computer-readable storage medium storing program instructions may be provided, execution of the program instructions resulting in operations comprising storing, by an apparatus, data on a first portion of a plurality of random access memories; and storing, by the apparatus, parity information for the stored data on a second portion of the plurality of random access memories.

The operations may further comprise dynamically varying a first amount of protected data and a second amount of unprotected data. A first size of the first region and a third size of the third region are dynamically variable. The operations may further comprise allocating a total memory space of the plurality of random access memories among a group consisting of the first region, the second region and the third region. The operations may further comprise reallocating a total memory space of the plurality of random access memories among a group consisting of the first region, the second region, the third region and a fourth region of the plurality of random access memories, where the fourth region consists of a portion of the plurality of random access memories that has been determined to be inaccessible or unusable. The operations may further comprise reallocating a total memory space of the plurality of random access memories among a group consisting of the first region, the second region, the third region and a fourth region of the plurality of random access memories, where the fourth region consists of a portion of the plurality of random access memories that is inaccessible or unusable. The first region, the second region and the third region do not overlap one another. The operations may further comprise using the parity information to reconstruct a lost or inaccessible portion of the protected data. The operations further comprise in response to an uncorrectable error occurring for one of the plurality of random access memories, continuing usage of remaining ones of the plurality of random access memories by using the parity information to reconstruct lost or inaccessible protected data. The parity information may enables reconstruction of a portion of protected data stored on a random access memory that fails. The operations further comprise writing new protected data to one of the plurality of random access memories; computing updated parity information based on the new protected data; and writing the updated parity information to the second region of the plurality of random access memories. The operations may further comprise in response to a command to write new protected data to a random access memory that has failed, reading other protected data from others of the plurality of random access memories and reading the parity information from the second region of the plurality of random access memories; reconstructing missing protected data for the failed random access memory based on the other protected data and the parity information; determining new parity information based on the new protected data and the reconstructed missing protected data; and writing the new parity information to the second region of the plurality of random access memories.

In one type of example apparatus, the apparatus may comprise at least one memory controller; and a plurality of random access memories, where the at least one memory controller is configured to allocate the plurality of random access memories among at least a first portion and a second portion, where the first portion is configured to store data, where the second portion is configured to store parity information for the stored data.

The at least one memory controller may be configured to dynamically vary a first amount of protected data and a second amount of unprotected data. The at least one memory controller may be configured to allocate a total memory space of the plurality of random access memories among a group consisting of the first region, the second region and the third region. The at least one memory controller may be configured to reallocate a total memory space of the plurality of random access memories among a group consisting of the first region, the second region, the third region and a fourth region of the plurality of random access memories, where the fourth region consists of a portion of the plurality of random access memories that has been determined to be inaccessible or unusable. The at least one memory controller may be configured to reallocate a total memory space of the plurality of random access memories among a group consisting of the first region, the second region, the third region and a fourth region of the plurality of random access memories, where the fourth region consists of a portion of the plurality of random access memories that is inaccessible or unusable. The at least one memory controller may be configured to use the parity information to reconstruct a lost or inaccessible portion of the protected data. The at least one memory controller may be configured to, in response to an uncorrectable error occurring for one of the plurality of random access memories, continue usage of remaining ones of the plurality of random access memories by using the parity information to reconstruct lost or inaccessible protected data. The at least one memory controller may be configured to write new protected data to one of the plurality of random access memories; compute updated parity information based on the new protected data; and write the updated parity information to the second region of the plurality of random access memories. The at least one memory controller is configured to in response to a command to write new protected data to a random access memory that has failed, read other protected data from others of the plurality of random access memories and reading the parity information from the second region of the plurality of random access memories; reconstruct missing protected data for the failed random access memory based on the other protected data and the parity information; determine new parity information based on the new protected data and the reconstructed missing protected data; and write the new parity information to the second region of the plurality of random access memories.

The exemplary embodiments of the invention, as discussed herein and as particularly described with respect to exemplary methods, may be implemented in conjunction with a program storage device (e.g., at least one memory) readable by a machine, tangibly embodying a program of instructions (e.g., a program or computer program) executable by the machine for performing operations. The operations comprise steps of utilizing the exemplary embodiments or steps of the method.

The blocks shown in FIGS. 8-10 further may be considered to correspond to one or more functions and/or operations that are performed by one or more components, circuits, chips, apparatus, processors, computer programs, functions, operations and/or function blocks. Any and/or all of the above may be implemented in any practicable solution or arrangement that enables operation in accordance with the exemplary embodiments of the invention as described herein.

In addition, the arrangement of the blocks depicted in FIGS. 8-10 should be considered merely exemplary and non-limiting. It should be appreciated that the blocks shown in FIGS. 8-10 may correspond to one or more functions and/or operations that may be performed in any order (e.g., any suitable, practicable and/or feasible order) and/or concurrently (e.g., as suitable, practicable and/or feasible) so as to implement one or more of the exemplary embodiments of the invention. In addition, one or more additional functions, operations and/or steps may be utilized in conjunction with those shown in FIGS. 8-10 so as to implement one or more further exemplary embodiments of the invention.

That is, the exemplary embodiments of the invention shown in FIGS. 8-10 may be utilized, implemented or practiced in conjunction with one or more further aspects in any combination (e.g., any combination that is suitable, practicable and/or feasible) and are not limited only to the steps, blocks, operations and/or functions shown in FIGS. 8-10.

Any use of the terms “connected,” “coupled” or variants thereof should be interpreted to indicate any such connection or coupling, direct or indirect, between the identified elements. As a non-limiting example, one or more intermediate elements may be present between the “coupled” elements. The connection or coupling between the identified elements may be, as non-limiting examples, physical, electrical, magnetic, logical or any suitable combination thereof in accordance with the described exemplary embodiments. As non-limiting examples, the connection or coupling may comprise one or more printed electrical connections, wires, cables, mediums or any suitable combination thereof.

Generally, various exemplary embodiments of the invention can be implemented in different mediums, such as software, hardware, logic, special purpose circuits or any combination thereof. As a non-limiting example, some aspects may be implemented in software which may be run on a computing device, while other aspects may be implemented in hardware.

Features as described herein may provide a selective redundant array of independent memory for a computer's main random access memory. This may utilize conventional RAM memory modules, and striping algorithms to protect against the failure of any particular module and keep the memory system operating continuously. It may support several DRAM device error checking and correcting (ECC) computer memory technologies that protects computer memory systems from any single memory chip failure, as well as multi-bit errors from any portion of a single memory chip, and entire memory channel failures. The features as described herein may be much more robust than parity checking and ECC memory technologies which cannot protect against many varieties of memory failures.

With features as described herein, not all of the data written or stored in the memory modules need be stored as protected data. The memory modules may store both protected data and unprotected data. Thus, not all of the data written to the memory modules needs to be provided with corresponding parity information. This may provide a “selective” redundancy for the array of independent memory where less than all of the data written or stored in the memory modules needs to have parity information also stored in the memory, and where the redundancy may be provided by data reconstruction of only the protected data (not the unprotected data) using parity information.

The foregoing description has provided by way of exemplary and non-limiting examples a full and informative description of the best method and apparatus presently contemplated by the inventors for carrying out the invention. However, various modifications and adaptations may become apparent to those skilled in the relevant arts in view of the foregoing description, when read in conjunction with the accompanying drawings and the appended claims. However, all such and similar modifications will still fall within the scope of the teachings of the exemplary embodiments of the invention.

Four (4) memory modules is the exemplary implementation described above. However, a minimum configuration may comprise 3 memory modules (2 memory modules of data and 1 memory module of parity). The parity may rotate across the memory modules. For any stripe of data, there may be 3 memory modules of data and 1 memory module of parity, but different stripes may put the parity information on different memory modules.

Furthermore, some of the features of the preferred embodiments of this invention could be used to advantage without the corresponding use of other features. As such, the foregoing description should be considered as merely illustrative of the principles of the invention, and not in limitation thereof.

What is claimed is:

1. A method comprising:
providing a plurality of random access memories having at least a first region, a second region and a third region;
storing protected data on the first region on at least two of the random access memories, where the protected data is stored distributed among the at least two random access memories of the first region;
storing parity information for the protected data on the second region on at least a third one of the random access memories; and
storing unprotected data on the third region.

2. The method of claim 1, further comprising: dynamically varying a first amount of protected data and a second amount of unprotected data.

3. The method of claim 1, where a first size of the first region and a third size of the third region are dynamically variable.

4. The method of claim 1, further comprising: allocating a total memory space of the plurality of random access memories among a group consisting of the first region, the second region and the third region.

5. The method of claim 1, further comprising: reallocating a total memory space of the plurality of random access memories among a group consisting of the first region, the second region, the third region and a fourth region of the plurality of random access memories, where the fourth region consists of a portion of the plurality of random access memories that has been determined to be inaccessible or unusable.

6. The method of claim 1, further comprising: reallocating a total memory space of the plurality of random access memories among a group consisting of the first region, the second region, the third region and a fourth region of the plurality of random access memories, where the fourth region consists of a portion of the plurality of random access memories that is inaccessible or unusable.

7. The method of claim 1, where the first region, the second region and the third region do not overlap one another.

8. The method of claim 1, further comprising: using the parity information to reconstruct a lost or inaccessible portion of the protected data.

9. The method of claim 1, further comprising: in response to an uncorrectable error occurring for one of the plurality of random access memories, continuing usage of remaining ones of the plurality of random access memories by using the parity information to reconstruct lost or inaccessible protected data.

10. The method of claim 1, where the parity information enables reconstruction of a portion of protected data stored on a random access memory that fails.

11. The method of claim 1, further comprising:
writing new protected data to one of the plurality of random access memories;
computing updated parity information based on the new protected data; and
writing the updated parity information to the second region of the plurality of random access memories.

12. The method of claim 1, further comprising:
in response to a command to write new protected data to a random access memory that has failed, reading other protected data from others of the plurality of random access memories and reading the parity information from the second region of the plurality of random access memories;
reconstructing missing protected data for the failed random access memory based on the other protected data and the parity information;
determining new parity information based on the new protected data and the reconstructed missing protected data; and
writing the new parity information to the second region of the plurality of random access memories.

13. The method of claim 1, where the plurality of random access memories consists of four memory modules.

14. The method of claim 1, where the plurality of random access memories consists of eight memory modules.

15. A method comprising:
providing a plurality of random access memories including a first region, a second region and a third region;
storing protected data on the first region on at least two of the random access memories;
storing parity information for the protected data on the second region on at least a third one of the random access memories;
storing unprotected data on the third region;
writing new protected data to the at least two random access memories;
computing updated parity information based on the new protected data; and
writing the updated parity information to the second region of the plurality of random access memories.

16. A method comprising:
providing a plurality of random access memories comprising a first region, a second region and a third region;
storing protected data on the first region on at least two of the random access memories;
storing parity information for the protected data on the second region on at least a third one of the random access memories;
storing unprotected data on the third region;
in response to a command to write new protected data to one of the random access memories that has failed of the at least two random access memories, reading other protected data from other ones of the at least two random access memories and reading the parity information from the second region;
reconstructing missing protected data for the failed random access memory based on the other protected data and the parity information;
determining new parity information based on the new protected data and the reconstructed missing protected data; and
writing the new parity information to the second region.
